(19) United States
(12) Patent Application Publication
(10) Pub. No.: US 2025/0237681 A1
(43) Pub. Date: Jul. 24, 2025

(54) GENERATING DEVICE OF PROGRAMMABLE QUANTUM VOLTAGES

(71) Applicant: NATIONAL INSTITUTE OF METROLOGY,CHINA, Beijing (CN)

(72) Inventors: Wenhui CAO, Beijing (CN); Jinjin LI, Beijing (CN); Erkun YANG, Beijing (CN); Yuan ZHONG, Beijing (CN); Qing ZHONG, Beijing (CN); Xueshen WANG, Beijing (CN); Xiaolong XU, Beijing (CN)

(21) Appl. No.: 19/026,874

(22) Filed: Jan. 17, 2025

(30) Foreign Application Priority Data
Jan. 18, 2024 (CN) 202410077418.6

(51) Int. Cl. G01R 19/10

(52) U.S. Cl. CPC G01R 19/10

(57) ABSTRACT

The present disclosure relates to a generating device of programmable quantum voltages. The method in the generating device of programmable quantum voltages includes: first, giving a source integer array and processing it to obtain a new array; comparing a number of Josephson junctions required for the target programmable voltage with each element in the new array according to a certain relationship; and based on the comparison results, selecting elements that meet the condition from the source array to finally obtain a target combination array. The source array can not only be binary or ternary but can also be in a special non-integer base. The method of the present disclosure enables integer expression calculations for arrays in all three bases, thereby selecting the appropriate number of junctions to output the quantum voltage.

### TECHNICAL FIELD

The present disclosure belongs to the technical field of metrology testing, and in particular relates to a generating device of programmable quantum voltages.

### BACKGROUND OF THE INVENTION

The Josephson junction array is segmented using a binary or ternary method, and after the operating frequency of the array is appropriately adjusted, the array can output any voltage value within a certain range. For instance, by using the binary segmentation method, the array is divided into N segments (N is an integer), each containing 2ⁿ elements (n=0, 1, 2, 3, . . . , N). If the required number of junctions m satisfies the following relationship, i.e.,

$$- {\sum }_{n = 0}^{N} {2}^{n} \leq m \leq {\sum }_{n = 0}^{N} {2}^{n} , then m = {\sum }_{n = 0}^{N} {b}_{n} {2}^{n} .$$

bₙ represents a binary state symbol. When m>0, bₙ can be selected to be in one of two states: 0 or 1; when m<0, bₙ can be selected to be in one of two states: −1 or 0.

For instance, by using the ternary segmentation method, the array is divided into N segments (N is an integer), each containing 3ⁿ elements (n=0, 1, 2, 3, . . . , N). If the required number of junctions m satisfies the flowing relationship, i.e.,

$$- {\sum }_{n = 0}^{N} {3}^{n} \leq m \leq {\sum }_{n = 0}^{N} {3}^{n} , then m = {\sum }_{n = 0}^{n} {b}_{n} {3}^{n} .$$

bₙ represents a ternary state symbol. At this point, regardless of the sign of m, bₙ has three states: −1, 0, and 1. However, the integer representation algorithms in binary or ternary systems in the current technology are limited to either binary or ternary algorithms. Therefore, there are many restrictions on their use, making them unsuitable for expressing and calculating integers in different systems. Furthermore, they are even more difficult to apply to integer representation calculations based on source arrays with non-integer bases.

In practical applications, for a device designed to include N segments of Josephson junctions, in the case of superconducting short circuits, that is, when the designed value of the number of junctions is different from the actual value, how to match the required number of junctions and generate quantum voltage is an urgent technical problem that needs to be solved.

### SUMMARY OF THE INVENTION

In order to overcome the above problems of the prior art, the present disclosure provides a generating device of programmable quantum voltages.

A generating device of programmable quantum voltages, comprises: a programmable quantum voltages sample, a data processing platform, a 16 channel current source, a Microwave source, a power amplifier, a liquid helium dewar, a Low temperature sample probe, a nanovoltmeter, and some Connection boxes;

the programmable quantum voltage device includes N segments of Josephson junction arrays, and the number of junctions in the Josephson junction array in each segment is a₁, wherein n=0, 1, 2, 3 . . . N; the segments are connected in series, and each segment is distinguished by the lead wire through which current is applied to the programmable quantum voltage device;

wherein, the data processing platform controls the 16 channel current source and the programmable quantum voltages sample to output the obtained quantum voltages on the nanovoltmeter:
S1, giving a source array aₙ i.e. N segments of Josephson junction arrays, and performing segmented summation on the source array to obtain a new array

$${c}_{n} = {\sum }_{n = 0}^{n} {a}_{n} + {a}_{0 ,}$$

wherein n=0, 1, 2, 3 . . . N, and the number of elements in the source array is the same as that in the new array;
S2, giving a number of junctions in the Josephson junction array that corresponds to a target voltage value, which serves as a target number of junctions m;
S3, comparing the target number of junctions m with each element c in the new array to determine whether a first preset relationship is satisfied, and if yes, selecting in the source array, which corresponds to the element cₙ, as one of the element that represents the target number of junctions m;
S4, subtracting aₙ from the target number of junctions m to obtain difference, comparing the absolute value of the difference with each element c in the new array to determine whether a second preset relationship is satisfied, if yes, selecting a, in the source array, which corresponds to the element cₓ, as one of the element represents the target number of junctions m;
S5, subtracting a, from difference obtained above to obtain further difference, denote the sign the new difference, comparing the absolute value of the new difference with each element cₙ in the new array to determine whether a second preset relationship is satisfied, if yes, selecting a, multiply with the sign of the difference denoted above in the source array, which corresponds to the element cₓ, as one of the element represents the target number of junctions m;
S6, determining whether the difference satisfy a constraint condition, if yes, stopping comparison and considering a group of elements found above as a target combination for representing the junctions number m.
Based on the aforementioned aspect and any possible implementation mode, an implementation mode is further provided in which the source array aₙ is binary or ternary or with a non-integer base.

Based on the aforementioned aspect and any possible implementation mode, an implementation mode is further provided in which the target number of junctions m is obtained as follows: at a given target operating frequency, the number of junctions in the Josephson junction array that corresponds to a target voltage value is acquired as the target number of junctions.

Based on the aforementioned aspect and any possible implementation mode, an implementation mode is further provided in which the preset relation in S3 is cₙ₋₁≤m<cₙ, wherein cₙ₋₁ and cₙ are adjacent two elements in the new array.

Based on the aforementioned aspect and any possible implementation mode, an implementation mode is further provided in which the second preset relationship is cₙ₋₁≤|difference|<cₙ, wherein cₙ₋₁ and cₙ are adjacent two elements in the new array.

Based on the aforementioned aspect and any possible implementation mode, an implementation mode is further provided in which the constraint condition is that the absolute value of the difference is smaller than a first element a₀ of the source array.

Based on the aforementioned aspect and any possible implementation mode, an implementation mode is further provided in which if the first preset relationship is not satisfied in S3, or if the second preset relationship is not satisfied in S5, operation is ended.

### Beneficial Effects of the Disclosure

Compared with the prior art, the present disclosure has the following beneficial effects:

The technical solution of the present invention can use a non-integer base method, so that even when individual junctions in the device have superconducting short circuits, that is, when the designed value of the number of junctions is different from the actual value, the required number of junctions can still be matched to generate quantum voltage; the method for segmenting the Josephson junction array in the present disclosure includes: first, giving a source array and processing it to obtain a new array; comparing a target number of junctions with each element in the new array according to a certain relationship; based on the comparison results, selecting elements that meet the condition from the source array to finally obtain a target combination array. The source array can not only be binary or ternary but can also be in a special non-integer base. The method of the present disclosure enables integer representation for arrays of all three aforementioned number bases.

### BRIEF DESCRIPTION OF DRAWINGS

FIG. 1 is a flowchart of the processing method of the generating device of programmable quantum voltages;

FIG. 2 is a schematic flowchart of Embodiment One of the processing method of the generating device of programmable quantum voltages;

FIG. 3 is a schematic flowchart of Embodiment Two of the processing method of the generating device of programmable quantum voltages;

FIG. 4 is a structural schematic drawing the generating device of programmable quantum voltages; and

FIG. 5 is a schematic diagram of generation of a programmable quantum voltage according to the present disclosure.

### DETAILED DESCRIPTION OF THE INVENTION

In order to better understand the technical solutions of the present disclosure, the content of the present disclosure includes, but is not limited to, the following detailed description, and similar techniques and methods should be regarded as being within the scope of protection of the present disclosure. In order to make the technical problems, technical solutions and advantages to be solved by the present disclosure more clear, the following will be described in detail with reference to the accompanying drawings and specific embodiments.

It should be understood that the described embodiments of the present disclosure are only some, but not all, embodiments of the present disclosure. Based on the embodiments in the present disclosure, all other embodiments obtained by those of ordinary skill in the art without making inventive labor, belong to the scope of protection of the present disclosure.

The terminology used in the embodiments of the disclosure is for the purpose of describing particular embodiments only and is not intended to limit the disclosure. As used in the embodiments of the present disclosure and the appended claims, the singular forms “a” and “the” are also intended to include the plurality of forms unless the context clearly indicates otherwise.

A generating device of programmable quantum voltages, comprises: a programmable quantum voltages sample, a data processing platform, a 16 channel current source, a Microwave source, a power amplifier, a liquid helium dewar, a Low temperature sample probe, a nanovoltmeter, and some Connection boxes.

The data processing platform is connected with the 16 channel current source, the Microwave source and the nanovoltmeter; the Microwave source is connected with the Low temperature sample probe, and the power amplifier is arranged between the Microwave source and the Low temperature sample probe; the 16 channel current source and the nanovoltmeter are connected with the Low temperature sample probe respectively through the Connection box; the Low temperature sample probe is inserted into the liquid helium dewar; and the programmable quantum voltages sample is arranged at the end of the Low temperature sample probe inserted into the liquid helium dewar.

The programmable quantum voltage device includes N segments of Josephson junction arrays, and the number of junctions in the Josephson junction array in each segment is a., wherein n=0, 1, 2, 3 . . . N; the segments are connected in series, and each segment is distinguished by the lead wire through which current is applied to the programmable quantum voltage device.

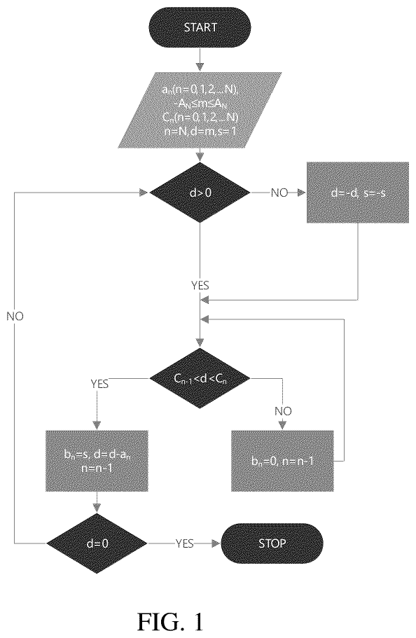

As shown in FIG. 1, the data processing platform controls the 16 channel current source and the programmable quantum voltages sample according to the following method to output the obtained quantum voltages on the nanovoltmeter:

for an integer m and a complete array a., in the figure, d=m is used for subsequent operations, and the method includes:
S1, a source array a, is given (i.e. N segments of Josephson junction arrays) and segmented summation is performed on the source array to obtain a new array, the formula is

$${c}_{n} = {\sum }_{n = 0}^{N} {a}_{n} + {a}_{0 ,}$$

wherein n=0, 1, 2, 3 . . . N, and by the algorithm formula of the new array, it can be seen that the number of elements in the source array is the same as that in the new array, and the array a, is integer;
S2, a number of junctions in the Josephson junction array that corresponds to a target voltage value is given, which serves as a target number of junctions m, m is an integer, and can be expressed as

$$m = {\sum }_{n = 0}^{N} {b}_{n} + {a}_{n} ,$$

aₙ is the source array, n=0, 1, 2, 3 . . . N, bₙ takes 0, 1 and −1; and
S3, the target number of junctions m is compared with each element cₙ in the new array to determine whether a first preset relationship is satisfied, and if yes, aₙ in the source array, which corresponds to the element cₙ, is selected as one element that represents the target number of junctions m, the sign of the integer m is determined, a positive voltage corresponds to a positive number and a negative voltage corresponds to a negative number. The value of the sign is assigned to s (assign s=1 for positive, s=−1 for negative, and s=0 for zero). If m<0, then m=|m|, i.e., an absolute value is taken.

The assigned m is compared with each element cₙ in the new array to determine whether a first preset relationship is satisfied, and if yes, aₙ in the source array, which corresponds to the element cₙ, is selected as a first element that represents the target number of junctions m; and an expansion coefficient corresponding to the first element satisfies bₙ=s.
S4, the first element is subtracted from the target number of junctions m to obtain a difference, the sign of the difference is determined again and is multiplied by a previous value of s, and a result is assigned to s. If the difference is less than 0, an absolute value of the difference is taken, then the absolute value is compared with each element cₙ in the new array to determine whether a second preset relationship is satisfied, and if yes, aₙ in the source array, which corresponds to the element cₙ, is selected as a second element that represents the target number of junctions m; and an expansion coefficient corresponding to the second element satisfies bₙ=s.
S5, whether the difference satisfies a constraint condition is determined, and if not, the second element is further subtracted from the difference to get a new difference, after the sign is determined, a result is further compared with the array cₙ to form a third element,
and step S5 is repeated. If the constraint condition is satisfied, the comparison is stopped and an array formed by the products of all the obtained first, second, . . . , and so on, elements with their corresponding expansion coefficients is considered as a target combination for representing the integer m.

Further, the source array aₙ is binary or ternary or in a non-integer base.

Further, the target number of junctions m is obtained as follows: at a given target operating frequency, the number of junctions in the Josephson junction array corresponding to the target voltage value is obtained as the target number of junctions. The voltage output of the programmable Josephson junction array is derived according to the formula:

$$V = m \frac{f}{{K}_{{}_{J}}} ,$$

wherein K_{J} is the Josephson constant, m is the number of Josephson junctions of outputting the voltage, and f is the operating frequency of the junction array.

Further, the preset relation in S3 is cₙ₋₁≤m<cₙ, wherein cₙ₋₁ and cₙ are adjacent two elements in the new array.

Further, the second preset relationship is cₙ₋₁≤difference<cₙ, wherein cₙ₋₁ and cₙ are adjacent two elements in the new array.

Further, the constraint condition is that the absolute value of the difference is smaller than a first element a₀ of the source array.

Further, if the first preset relationship is not satisfied in S3, or if the second preset relationship is not satisfied in S5, operation is ended.

In particular, the subsequent operations of this disclosure are as follows: the method of this disclosure is based on the comparison approach, where segments matching the target number of junctions are found through comparison. Therefore, it can be applied to both binary and ternary segmentation methods, as well as non-integer base segmentation methods. The specific steps are as follows:

First step, a complete source array is taken, and elements of the source array satisfy the relationship of 0<aₙ₋₁<aₙ₊₁/3≤aₙ≤3aₙ₋₁, and segmented summation is performed on the source array to form a new summation array. The new array has the same number of elements as the source array. The source array is denoted as aₙ, wherein n=0, 1, 2, 3 . . . , and the new array obtained by segmenting and summing the source array is denoted as

$${c}_{n} = {\sum }_{n = 0}^{N} {a}_{n} + {a}_{0 ,}$$

wherein n=0, 1, 2, 3 . . . N;

Second step, the target value m needs to be obtained via the formula

$$V = m \frac{f}{{K}_{{}_{J}}} ,$$

first, there is a desired output voltage V, the operating frequency is also a known value, and K_{J} is a constant. Through calculation,

$$m = V \frac{{K}_{{}_{J}}}{f}$$

can be obtained and m is compared with each element cₙ (n=0, 1, 2, 3 . . . ) in the new array. If the target value satisfies the relationship of cₙ₋₁≤m<cₙ, then aₙ is selected as an array element to represent m.

Third step, the second step is repeated. After comparing with all cₙ values, only one cₙ will satisfy the condition. aₙ is subtracted from m, i.e., m′=m−aₙ, to obtain a remainder or difference. Then, compare this remainder or difference with the array element cₙ (n=0, 1, 2, 3, . . . , N), and cₙ₋₁≤difference<cₙ. After comparison, an element is selected. If the absolute value of the result of subtracting the selected element from this difference is greater than a₀, then this step is repeated to continuously select the next element to represent m;

Fourth step, the third step is repeated until the absolute value of the remainder or the difference is less than a₀, and the array elements aₙ that can represent m are all found.

The following is illustrated by specific embodiments:

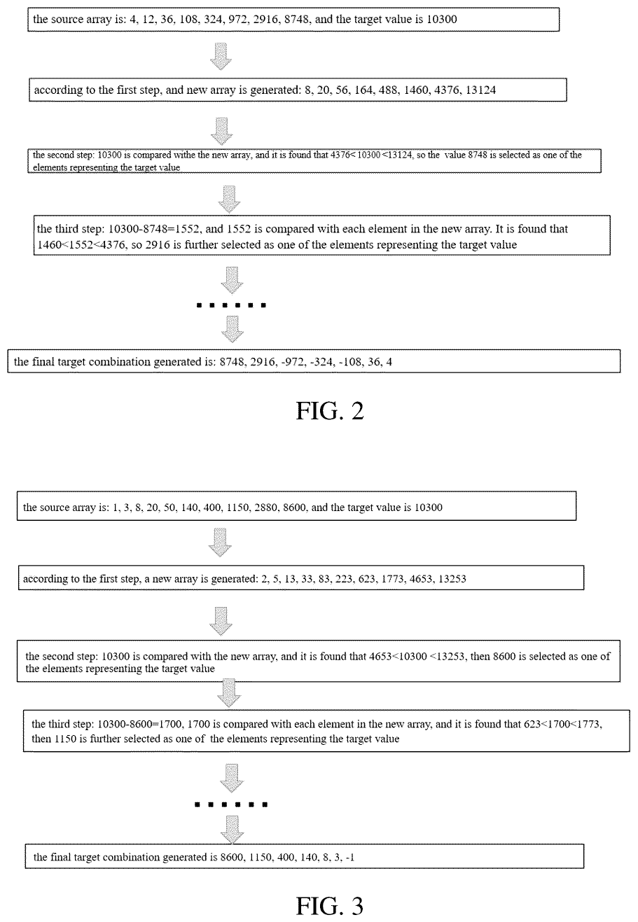

As shown in FIG. 2, the segmentation of a ternary programmable Josephson junction array is presented, with the source array being: 4, 12, 36, 108, 324, 972, 2916, 8748. The segmentation method of this disclosure is then used to match a target value, such that the array operates near 19 GHz and outputs a voltage of 0.4047 volts. According to calculations, approximately 10300 Josephson junctions are needed, which serves as the target number of junctions m. Following the first step described previously, a new array is obtained: 8, 20, 56, 164, 488, 1460, 4376, 13124. According to the second step, 10300 is compared with each element in the new array, and it is found that 4376<10300<13124, so the a, with the value 8748 from the source array is selected as one of the elements representing the target number of junctions m. In the third step, the difference between m and a, is calculated, i.e., 10300−8748=1552, and 1552 is then compared with each element in the new array. It is found that 1460<1552<4376, so 2916 from the source array, which corresponds to 4376 in the new array, is further selected as one of the elements representing the target number of junctions m. This third step is repeated until the absolute value of the remainder or the difference is less than a₀. The final target combination generated is: 8748, 2916, −972, −324, −108, 36, 4. The negative numbers are due to the expansion coefficient bₙ.

### Embodiment 2

The segmentation of a complete non-integer-based programmable Josephson junction array is: 1, 3, 8, 20, 50, 140, 400, 1150, 2880, 8600. These segments are then used to match a target value, again it is ensured that the array operates near 19 GHz and outputs a voltage of 0.4047 volts. Based on the voltage output formula from the previous section, calculations indicate that approximately 10300 Josephson junctions are needed. The calculation process is shown in FIG. 3, and the final target combination obtained is: 8600, 1150, 140, 400, 8, 3, 1.

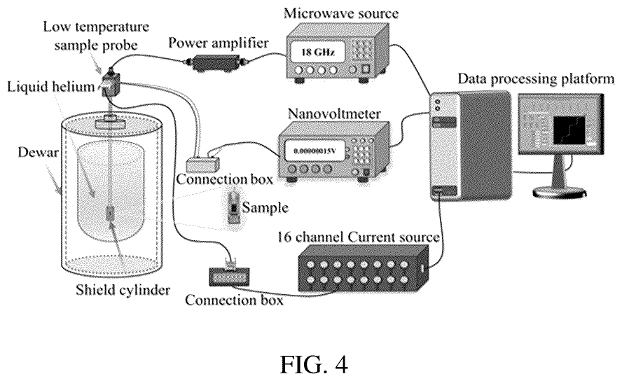

The segmentation method of this disclosure is applied in the generation of programmable quantum voltages and has achieved excellent results. As shown in FIG. 4, a generating device of programmable quantum voltages, comprises: a programmable quantum voltages sample, a data processing platform, a 16 channel current source; a Microwave source; a power amplifier; a liquid helium dewar, a Low temperature sample probe, a nanovoltmeter, and some Connection boxes.

The data processing platform is connected with the 16 channel current source, the Microwave source and the nanovoltmeter; the Microwave source is connected with the Low temperature sample probe, and the power amplifier is arranged between the Microwave source and the Low temperature sample probe; the 16 channel current source and the nanovoltmeter are connected with the Low temperature sample probe respectively through the Connection box; the Low temperature sample probe is inserted into the liquid helium dewar, and the programmable quantum voltages sample is arranged at the end of the Low temperature sample probe inserted into the liquid helium dewar.

The programmable quantum voltage device includes N segments of Josephson junction arrays, and the number of junctions in the Josephson junction array in each segment is a., wherein n=0, 1, 2, 3 . . . N; the segments are connected in series, and each segment is distinguished by the lead wire through which current is applied to the programmable quantum voltage device.

As shown in FIG. 4, the sample marked in the figure contains N segments of Josephson junctions array, and the number of Josephson junctions in each segment is a., and the segments are connected in series. Each segment can be distinguished by the lead wire through which current is applied to the sample. For example, if current is applied to aₙ, the corresponding current source channel is used. When current is applied, this segment will work, and when no current is applied, this segment will not work. When it is required to output a 1V voltage, the number of junctions corresponding to the 1V voltage is calculated firstly, and we can adjust the frequency slightly so that the required number of junctions is an integer. Then, through the technical solution of the present invention, the corresponding segments are selected and input into the current source. The current source drives these segments, and with the microwave input from the microwave source and the power amplifier, a 1V quantum voltage is generated. Thus, the technical solution of the present invention can use a non-integer base method, so that even when individual junctions in the device have superconducting short circuits, that is, when the designed value of the number of junctions is different from the actual value, the required number of junctions can still be matched to generate quantum voltage.

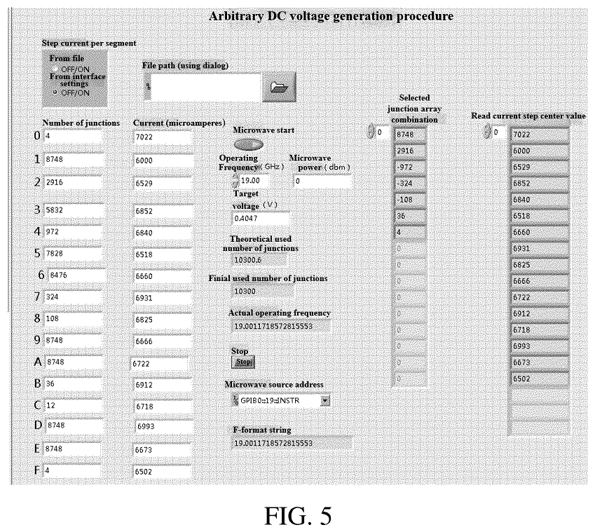

As shown in FIG. 5, with an input voltage of 0.4047 volts, the first step is to calculate that 10300 junctions are required. Then, the segmentation method of this disclosure is invoked to select a combination of ternary junction array elements. By fine-tuning the microwave frequency, a voltage of 0.4047 volts is output.

As a disclosed embodiment of the present disclosure, an apparatus of segmenting a Josephson junction array is also provided for implementing the method of the present disclosure, wherein the apparatus includes: a first giving module, configured to give a source array aₙ and perform segmented summation on the source array to obtain a new array

$${c}_{n} = {\sum }_{n = 0}^{N} {a}_{n} + {a}_{0 ,}$$

wherein n=0, 1, 2, 3 . . . N, and the number of elements in the source array is the same as that in the new array;
a second giving module, configured to give a number of junctions in the Josephson junction array that corresponds to a target voltage value, which serves as a target number of junctions m;
a first comparing module, configured to compare the target number of junctions m with each element cₙ in the new array to determine whether a first preset relationship is satisfied, and if yes, select aₙ in the source array, which corresponds to the element cₙ, as one of the elements that represents the target number of junctions m;
a second comparing module, subtracting aₙ from the target number of junctions m to obtain difference, comparing the absolute value of the difference with each element cₙ in the new array to determine whether a second preset relationship is satisfied, if yes, selecting aₓ in the source array, which corresponds to the element cₓ, as one of the element represents the target number of junctions m; and
a third comparing module, subtracting aₓ from difference obtained above to obtain further difference, denote the sign the new difference, comparing the absolute value of the new difference with each element cₙ in the new array to determine whether a second preset relationship is satisfied, if yes, selecting aₓ multiply with the sign of the difference denoted above in the source array, which corresponds to the element cₓ, as one of the element represents the target number of junctions m;
a constraint module, configured to determine whether the differences satisfy a constraint condition, if yes, stop comparison and consider a group of second array elements formed by all the second array elements as a target combination.

An embodiment of the present disclosure further provides an electronic device including:
a memory storing executable instructions; and
a processor that runs the executable instructions in the memory to implement the method of the present disclosure.

An embodiment of the present disclosure further provides a computer-readable storage medium having stored there on a computer program which, when executed by a processor, implements the method of the present disclosure.

While the foregoing description has shown and described several preferred embodiments of the present disclosure, it should be understood that the present disclosure is not limited to the form disclosed herein and should not be regarded as an exclusion of other embodiments, but can be used in various other combinations, modifications and contexts, and can be modified by the above teachings or skill or knowledge in the related art within the scope of the application described herein. Alterations and changes made by those skilled in the art without departing from the spirit and scope of the present disclosure should be within the scope of protection of the appended claims.

1. A generating device of programmable quantum voltages, comprising: a programmable quantum voltages sample, a data processing platform, a 16 channel current source, a Microwave source, a power amplifier, a liquid helium dewar, a Low temperature sample probe, a nanovoltmeter, and some Connection boxes;
the programmable quantum voltage device includes N segments of Josephson junction arrays, and the number of junctions in the Josephson junction array in each segment is aₙ, wherein n=0, 1, 2, 3 . . . N; the segments are connected in series, and each segment is distinguished by the lead wire through which current is applied to the programmable quantum voltage device;
wherein, the data processing platform controls the 16 channel current source and the programmable quantum voltages sample according to the following method to output the obtained quantum voltages on the nanovoltmeter:
S1, giving a source array aₙ, i.e. N segments of Josephson junction arrays, and performing segmented summation on the source array to obtain a new array
$${c}_{n} = {\sum }_{n = 0}^{N} {a}_{n} + {a}_{0 ,}$$
wherein n=0, 1, 2, 3 . . . N, and the number of elements in the source array is the same as that in the new array;
S2, giving a number of junctions in the Josephson junction array that corresponds to a target voltage value, which serves as a target number of junctions m;
S3, comparing the target number of junctions m with each element cₙ in the new array to determine whether a first preset relationship is satisfied, and if yes, selecting in the source array, which corresponds to the element cₙ, as one of the element that represents the target number of junctions m;
S4, subtracting aₙ from the target number of junctions m to obtain difference, comparing the absolute value of the difference with each element cₙ in the new array to determine whether a second preset relationship is satisfied, if yes, selecting aₓ in the source array, which corresponds to the element cₓ, as one of the element represents the target number of junctions m;
S5, subtracting a, from difference obtained above to obtain further difference, denote the sign the new difference, comparing the absolute value of the new difference with each element cₙ in the new array to determine whether a second preset relationship is satisfied, if yes, selecting aₓ multiply with the sign of the difference denoted above in the source array, which corresponds to the element cₓ, as one of the element represents the target number of junctions m;
S6, determining whether the difference satisfy a constraint condition, if yes, stopping comparison and considering a group of elements found above as a target combination for representing the junctions number m.

2. The generating device of programmable quantum voltages according to claim 1, wherein the source array aₙ is binary or ternary or with a non-integer base.

3. The generating device of programmable quantum voltages according to claim 1, wherein the target number of junctions m is obtained as follows: at a given target operating frequency, the number of junctions in the Josephson junction array that corresponds to a target voltage value is acquired as the target number of junctions.

4. The generating device of programmable quantum voltages according to claim 1, wherein the preset relation in S3 is cₙ₋₁≤m<cₙ, wherein n=0, 1, 2, 3 . . . N, cₙ₋₁ and cₙ are adjacent two elements in the new array.

5. The generating device of programmable quantum voltages according to claim 1, wherein the second preset relationship is cₓ₋₁≤|difference|<cₓ, wherein x=0, 1, 2, 3 . . . N, cₓ₋₁ and cₓ are adjacent two elements in the new array.

6. The generating device of programmable quantum voltages according to claim 1, wherein the constraint condition is that the absolute value of the difference is smaller than the first element a₀ of the source array.

7. The generating device of programmable quantum voltages according to claim 1, wherein if the first preset relationship is not satisfied in S3, or if the second preset relationship is not satisfied in S5, operation is ended.
